(19) United States
(12) Patent Application Publication
(10) Pub. No.: US 2025/0324789 A1
(43) Pub. Date: Oct. 16, 2025

(54) IMAGING MODULE AND IMAGING APPARATUS

(71) Applicant: CANON KABUSHIKI KAISHA, Tokyo (JP)

(72) Inventors: HIROKI SAITO, Kanagawa (JP); TOSHIYUKI YOSHIDA, Kanagawa (JP); KEISUKE ABE, Kanagawa (JP)

(21) Appl. No.: 19/086,452

(22) Filed: Mar. 21, 2025

(30) Foreign Application Priority Data
Apr. 16, 2024 (JP) 2024-066313

(51) Int. Cl. H10F 39/00; H10F 39/18

(52) U.S. Cl. CPC H10F 39/804; H10F 39/18

(57) ABSTRACT

An imaging module includes: a substrate; an imaging element mounted on the substrate; a frame body including a plurality of side portions and a corner portion and provided outside the imaging element in a plan view; a first bonding member provided between the substrate and the frame body; a lid body that is translucent and covers a space formed by the substrate and the frame body; and a second bonding member provided between the frame body and the lid body, wherein a thickness of the second bonding member at a middle portion of the side portion is thicker than a thickness of the second bonding member at the corner portion.

### BACKGROUND

### Field of the Invention

The present invention relates to an imaging module and an imaging apparatus.

### Description of the Related Art

Image sensor packages using CCD (Charge Coupled Device) image sensors and CMOS (Complementary Metal Oxide Semiconductor) image sensors used in imaging apparatuses such as digital cameras and video cameras are semiconductor modules with hollow structures. A semiconductor module with a hollow structure is provided with a wiring board on which a semiconductor element is mounted, a frame-shaped member provided at the outer edge of a mounting region of the semiconductor element, and a translucent lid body, and has a structure in which the translucent lid body is mounted from above the wiring board by a bonding member so as to seal the semiconductor element in the hollow.

Japanese Patent Application Laid-Open No. 2014-167990 discloses a highly planar electronic component including a base having an arrangement region of an electronic device, a frame body having an opening corresponding to the arrangement region and adhered to the base, a lid body adhered to the upper surface of the frame body with an adhesive having a uniform thickness, and the electronic device fixed to the base.

When the lid body is adhered to the frame body having a high planarity with a uniform thickness, as in the case of the electronic component described in Japanese Patent Application Laid-Open No. 2014-167990, the translucent lid body is heated by heat dissipation caused by the operational heat generation of the imaging element, and temperature unevenness may occur in the translucent lid body.

### SUMMARY

Therefore, it is an object of the present disclosure to provide an imaging module capable of suppressing distortion of the lid body caused by the operational heat generation of the imaging element.

According to one aspect of the present disclosure, there is provided an imaging module including: a substrate; an imaging element mounted on the substrate; a frame body including a plurality of side portions and a corner portion and provided outside the imaging element in a plan view; a first bonding member provided between the substrate and the frame body; a lid body that is translucent and covers a space formed by the substrate and the frame body; and a second bonding member provided between the frame body and the lid body, wherein a thickness of the second bonding member at a middle portion of the side portion is thicker than a thickness of the second bonding member at the corner portion.

Further features of the present invention will become apparent from the following description of exemplary embodiments with reference to the attached drawings.

### BRIEF DESCRIPTION OF THE DRAWINGS

FIG. 1 is a top view illustrating an imaging module according to a first embodiment.

FIG. 2A is a cross-sectional view illustrating the imaging module according to the first embodiment.

FIG. 2B is a cross-sectional view illustrating an imaging module according to the first embodiment.

FIG. 3 is a top view illustrating a frame in the imaging module according to the first embodiment.

FIG. 4 is a cross-sectional view illustrating an imaging module of Example 6.

FIG. 5 is a cross-sectional view illustrating an imaging module of Example 7.

FIG. 6 is a cross-sectional view illustrating an imaging module of Comparative Example 1.

FIG. 7 is a cross-sectional view illustrating an imaging module of Comparative Example 2.

FIG. 8 is a sectional view illustrating an imaging module of Comparative Example 3.

FIG. 9 is a schematic view illustrating electronic equipment according to a second embodiment.

### DESCRIPTION OF THE EMBODIMENTS

Hereinafter, embodiments of the present invention will be described with reference to the drawings. However, the embodiments described below are some embodiments of the present invention and the present invention is not limited thereto. Then, common configurations will be described by mutually referring to a plurality of drawings, and configurations with common reference numerals will be omitted be omitted from the explanation as appropriate.

When a lid body is bonded to a frame body having a high flatness with a uniform thickness, such as in the electronic component described in Japanese Patent Application Laid-Open No. 2014-167990, the translucent lid body is heated by heat dissipation caused by the operational heat generation of the imaging element. At this time, in the temperature distribution of the translucent lid body, the temperature of the middle portion of the lid body opposed to the imaging element is the highest, and the temperature decreases concentrically toward the corners, with the lowest temperature at the corners of the lid body. The temperature unevenness generated in the translucent lid body generates thermal stress in the translucent lid body due to the thermal expansion difference in the surface of the translucent lid body, thereby causing distortion in the translucent lid body. When distortion is generated in the translucent lid body, deviation is caused in the optical axis of light entering the imaging element through the translucent lid body, which makes the image quality of the captured image deteriorated. Such deterioration in image quality has become even more problematic in recent years, as the translucent lid body has been required to be thinner from the viewpoint of miniaturization and weight reduction.

### First Embodiment

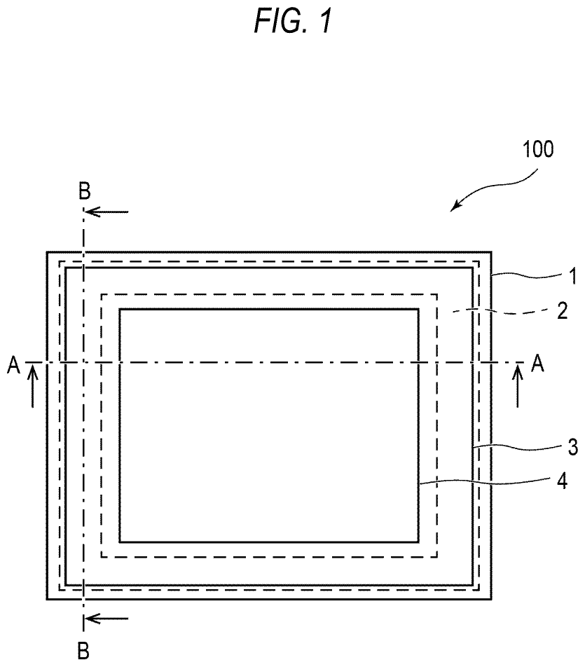

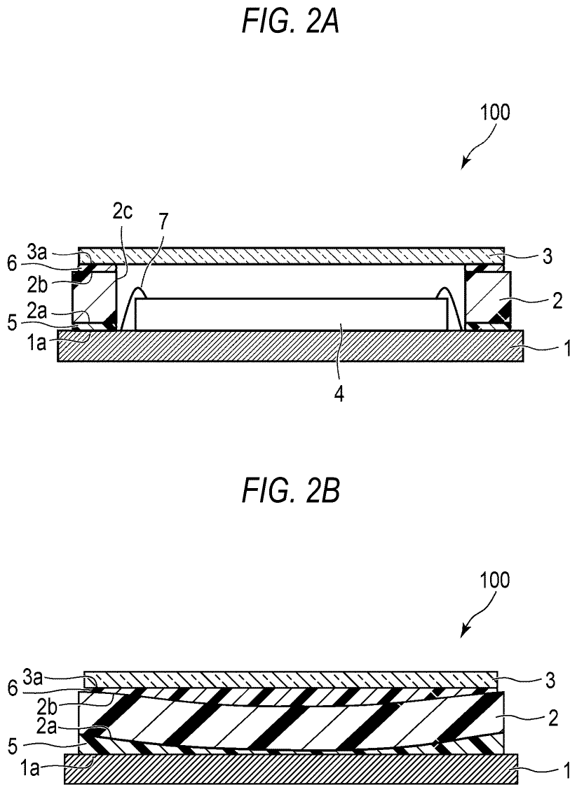

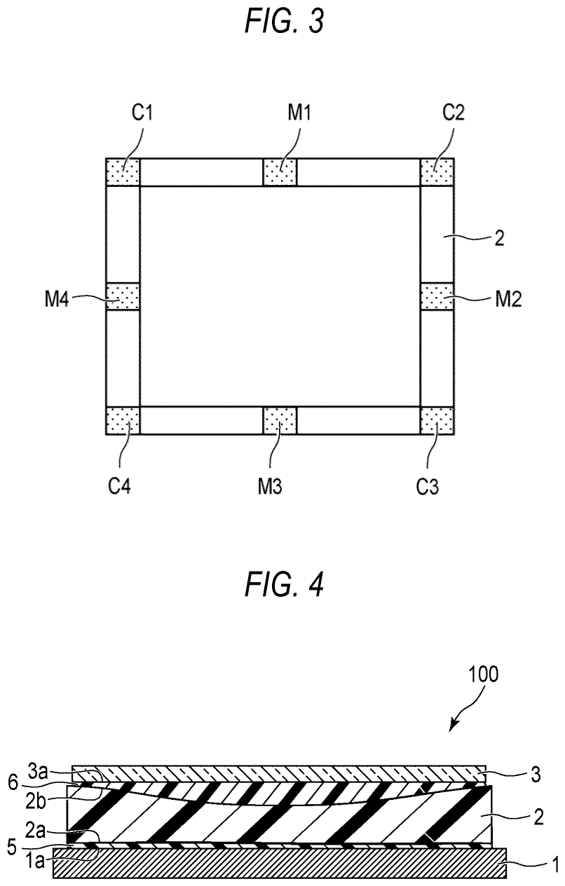

An imaging module according to a first embodiment of the present disclosure will be described with reference to FIG. 1 to FIG. 3. FIG. 1 is a top view illustrating an imaging module 100 according to the present embodiment. FIG. 2B is a cross-sectional view illustrating a cross section along a line A-A illustrated in FIG. 1 of the imaging module 100 according to the present embodiment. FIG. 2B is a cross-sectional view illustrating a cross section along line B-B illustrated in FIG. 1 of the imaging module 100 according to the present embodiment. Note that, in FIG. 2A and FIG. 2B, portions between a substrate 1 and a frame body 2 and portions between the frame body 2 and a lid body 3 are exaggerated in the thickness direction. FIG. 3 is a top view illustrating the frame body 2 of the imaging module 100 according to the present embodiment.

As illustrated in FIG. 1 to FIG. 2B, the imaging module 100 according to the present embodiment includes a substrate 1, a frame body 2, a lid body 3, and an imaging element 4.

The imaging element 4 is arranged and mounted on one surface 1a of the substrate 1. The imaging element 4 mounted on the substrate 1 is arranged at, for example, the center of the substrate 1. The imaging element 4 is electrically connected to the substrate 1 by metal wirings 7.

The frame body 2 is arranged on the surface 1a of the substrate 1 on which the imaging element 4 is arranged so as to surround the imaging element 4 outside the imaging element 4 in a plan view perpendicular to the substrate 1. The substrate 1 and the frame body 2 are bonded to each other by a first bonding member 5. More specifically, the surface 1a of the substrate 1 is bonded to one surface 2a of the frame body 2 by the first bonding member 5. Thus, the frame body 2 is bonded to the substrate 1 by the first bonding member 5 so as to surround the imaging element 4.

As illustrated in FIG. 3, the frame body 2 has an annular planar shape surrounding a rectangular region including the imaging element 4 in a plan view viewed perpendicular to the substrate 1. In FIGS. 3, M1 to M4 represent the middle portions of the side portions of the frame body 2, and C1 to C4 represent the corner portions of the frame body 2. Note that the planar shape of the frame body 2 is not limited to the planar shape illustrated in FIG. 3, but may be an annular planar shape surrounding a polygonal area other than a rectangle area including the imaging element 4 in a plan view viewed perpendicular to the substrate 1. That is, the frame body 2 is a frame-shaped member having a frame-shaped shape having a plurality of side portions and a plurality of corner portions each connecting two adjacent side portions. Note that the frame body 2 may be arranged so as to surround the imaging element 4 even if the side portions are not formed continuously and do not surround the imaging element 4.

The lid body 3 is arranged on the other surface 2b of the frame body 2 so as to seal the opening 2c of the frame body 2. The frame body 2 and the lid body 3 are bonded by a second bonding member 6. More specifically, the other surface 2b of the frame body 2 and one surface 3a of the lid body 3 are bonded by the second bonding member 6. Thus, the lid body 3 is bonded onto the frame body 2 by the second bonding member 6. The lid body 3 covers the space formed by the substrate 1 and the frame body 2 so as to seal the space.

In the imaging module 100 according to the present embodiment, the thickness of the second bonding member 6 bonding the frame body 2 and the lid body 3 is made thicker at the middle portion of the side portion of the frame body 2 than at the corner portion of the frame body 2. With the second bonding member 6 having such a thickness provided, the heat transmitted from the imaging element 4 and the substrate 1, which are heat generation sources, can be efficiently transferred to the corner portion of the lid body 3 having a low temperature using the frame body 2 as a heat transfer path. Thus, temperature unevenness of the lid body 3 can be reduced, and distortion of the lid body 3 can be suppressed to a small degree. In this way, according to the present embodiment, distortion of the lid body 3 caused by the operational heat generation of the imaging element 4 can be suppressed.

Hereinafter, each component of the imaging module 100 according to the present embodiment will be described in detail.

The substrate 1 can be formed by laminating plate materials. Specifically, the substrate 1 is a wiring board having on its surface, or having on its surface and inside, wiring, electrodes, and the like for electrical connection between components. As the substrate 1, for example, a printed wiring board, a printed circuit board, a glass composite substrate, a glass epoxy substrate, a ceramic substrate, or the like can be used.

In order to mount the imaging element 4 on the substrate 1, the substrate 1 has electrodes (not illustrated) patterned in advance on the surface la which is the mounting surface thereof. The electrodes may be provided not only on one surface la of the substrate 1 but also on the other surface 2b of the substrate 1. The substrate 1 may be made of a conductive material such as a metal plate as long as insulation of the internal terminal and the external terminal can be ensured, but typically the substrate 1 is made of an insulator. The thickness of the substrate 1 is not limited to a specific thickness, but is in the range of 0.1 mm or more and 3 mm or less, for example.

The frame body 2 is a frame-shaped member arranged on the surface 1a of the substrate 1 on which the imaging element 4 is mounted so as to surround the region on which the imaging element 4 is mounted. The frame body 2 surrounds the imaging element 4 in a plan view viewed perpendicular to the substrate 1. The frame body 2 is bonded to the surface la of the substrate 1 by the first bonding member 5.

As the material of the frame body 2, resins, ceramics, metals including alloys and the like can be suitably used. The frame body 2 is preferably composed of a cured product of a thermosetting resin composition from the viewpoint of miniaturization, weight reduction and reduced warpage of the imaging module 100. The frame body 2 preferably has a rectangular outer shape. The thickness of the frame body 2 needs to be thicker than that of the imaging element 4 to accommodate the imaging element 4, and is preferably in the range of 0.5 mm or more and 3.0 mm or less.

The frame body 2 has a frame-like shape with the side portions connected by the corner portions as described above. In this case, the distance from the middle portion of the side portion of the frame body 2 to the lid body 3 is preferably longer than the distance from the corner portion of the frame body 2 to the lid body 3. On the other hand, the distance from the corner portion of the frame body 2 to the substrate 1 is preferably longer than the distance from the middle portion of the frame body 2 to the substrate 1.

The side portion of the frame body 2 preferably has a convex warpage protruding toward the side of the substrate 1. It is practical that the warpage amount is preferably 10 μm or more and more preferably in the range of 10 μm or more and 100 μm or less. When the warpage amount is in the range of 10 μm or more and 100 μm or less, a sufficient amount of the bonding member can be provided in the middle portion of the side portion of the frame body 2, so that heat transferred from the substrate 1 or the imaging element 4 can be efficiently transferred from the corner portion to the lid body 3 through the frame body 2. When the warpage amount is less than 10 μm, the heat transfer from the middle portion of the side portion of the frame body 2 to the lid body 3 becomes large, and the heat transfer efficiency to the lid body 3 through the corner portion of the frame body 2 is lowered, which may make it difficult to equalize the heat of the lid body 3. On the other hand, when the warpage amount is greater than 100 μm, the change in the external dimension of the frame body 2 due to the warpage makes it difficult to handle the frame body 2 in the assembly process, which may reduce productivity.

Note that the warpage amount of the frame body 2 is expressed by the height of the middle portion of the side portion including the corner portion of the frame body 2 from a reference line connecting the adjacent corner portions of the frame body 2. The shape of the warpage of the frame body 2 is not particularly limited and may have various shapes. For example, the shape of the warpage of the frame body 2 may be an arc-like shape overall in the length direction of the side, a shape that is straight from the corner portions to the middle portion of the side portion with a bend in the middle portion, or a shape bulging in a convex shape in which only the corner portion is protruded toward the side of the lid body 3.

The flatness of the frame body 2 having the above-described shape is preferably 100 μm or less. When the flatness of the frame body 2 is 100 μm or less, higher stability can be ensured in both the bonding with the substrate 1 by the first bonding member 5 and the bonding with the lid body 3 by the second bonding member 6. Further, the deterioration of image quality due to the deviation of the optical axis caused by the parallelism between the imaging element 4 on the substrate 1 and the lid body 3 can be suppressed. When the warpage amount is larger than 100 μm, the handling of the frame body 2 in the assembly process becomes difficult due to the change of the external dimension of the frame body 2, and productivity may decrease.

Further, the surface of the frame body 2 may be roughened to form concavities and convexities. As the surface is roughened, the surface area of the frame body 2 increases, and the heat transfer efficiency in the thickness direction is increased from the lower surface to the upper surface of the frame body 2. In addition, when the frame body 2 is composed of a cured product of a resin composition containing a filler, the skin layer, which is a layer on the surface of the frame body 2, may be removed and the filler may be exposed. In this case, a filler having a higher thermal conductivity than the resin can be used as a heat transfer path to achieve higher heat transfer efficiency.

The thermal conductivity of the frame body 2 is preferably larger than those of the first bonding member 5 and the second bonding member 6. Due to the large and small relationship of the thermal conductivity, higher heat transfer efficiency can be realized. As the thermal conductivity of the frame body 2 is larger than the thermal conductivities of the first bonding member 5 and the second bonding member 6, heat generated from the imaging element 4 can be efficiently transferred to the lid body 3 through the frame body 2, and the lid body 3 can be made more thermally uniform. The thermal conductivity of the frame body 2 is more preferably 1.1 times or more than the thermal conductivities of the first bonding member 5 and the second bonding member 6.

Further, in order to efficiently transfer heat generated by heat generation of the imaging element 4 and transmitted from the substrate 1 to the frame body 2 to the lid body 3 via the substrate 1, the thermal conductivity of the frame body 2 is preferably 1.0 W/m·K or more.

Note that, as illustrated in FIG. 2A, the frame body 2 is arranged only on the side of one surface la of the substrate 1, but the arrangement of the frame body 2 is not limited thereto. For example, the frame body 2 may be arranged to cover the side of the side surface the substrate 1, or may be arranged to cover the side of the side surface of the lid body 3.

Hereinafter, when the frame body 2 is composed of a cured product of a thermosetting resin composition, constituent materials of the thermosetting resin composition and a method of manufacturing the frame body 2 will be described in detail.

The thermosetting resin composition forming the frame body 2 may contain an epoxy resin, a curing agent, a filler, an additive and the like as the constituent material.

Examples of the epoxy resin included in the thermosetting resin composition include triphenylmethane type epoxy resins, dicyclopentadiene type epoxy resins, naphthol-cresol-novolac type epoxy resins, multifunctional epoxy resins, bisphenol A type epoxy resins, bisphenol F epoxy resins, cyclic aliphatic epoxy resins, long-chain aliphatic epoxy resins, glycidyl ester epoxy resins, glycidyl amine epoxy resins, and the like. Among them, a polyfunctional epoxy resin having a small epoxy equivalent and excellent in heat resistance, chemical resistance and electrical characteristics is preferable. The content of the epoxy resin in the resin composition for bonding is preferably in the range of, for example, 3 mass % or more and 25 mass % or less.

Examples of the curing agent included in the thermosetting resin composition include materials in which a curing reaction occurs with respect to the epoxy resin such as amine-based curing agents (aliphatic amines, aromatic amines, and the like), imidazole-based curing agents, acid anhydride curing agents, novolac type phenolic resin curing agents, and the like. Among them, a novolac type phenolic resin curing agent having high crosslinking density of the cured product and excellent in heat resistance, moisture resistance, chemical resistance, and the like is preferable. The amount of the curing agent to the epoxy resin is determined by the amount of the epoxy resin blended and the equivalent amounts of the reactive functional groups of the epoxy resin and the curing agent.

The filler included in the thermosetting resin composition is used to adjust the linear expansion coefficient, the elastic modulus and the thermal conductivity. When the linear expansion coefficient and the elastic modulus of the frame body 2 are significantly different from those of the substrate 1 and the lid body 3, there is a possibility that a joint failure occurs between the frame body 2 and the substrate 1 or the lid body 3 as a result of a large strain at the bonding interface due to thermal deformation of the substrate 1 or the lid body 3 caused by reflow heating during the bonding or the mounting of the imaging element 4 and the components. As the filler, an inorganic filler is preferable, and examples of the filler include silica particles such as spherical silica, crystalline silica, and the like, aluminum oxide, titanium oxide, zirconium oxide, magnesium oxide, calcium silicate, calcium carbonate, potassium titanate, silicon carbide, silicon nitride, boron nitride, aluminum nitride, and the like. The inorganic filler may be used alone or in combination with two or more kinds. Among them, silica particles having a small linear expansion coefficient are preferable from the viewpoint of adjusting the linear expansion coefficient of the frame body 2, and particles of calcium carbonate are preferable from the viewpoint of adjusting the elastic modulus of the frame body 2.

The ratio of the silica particles in the thermosetting resin composition when adjusting the linear expansion coefficient is preferably in the range of 60 mass % or more and 95 mass % or less to keep the difference in the linear expansion coefficient between the frame body 2 and the substrate 1 and the lid body 3 preferably 10 ppm/K or less. Further, the ratio of the silica particles is more preferably in the range of 65 mass % or more and 90 mass % or less.

In order to fill the silica particles in a high degree, it is preferable to mix two or more kinds of the silica particles having different central particle diameters. More specifically, it is preferable that the silica particles having a large particle diameter have a central particle diameter of 10 μm or more and that the silica particles having a small particle diameter have a central particle diameter of 1 μm or less. Further, it is more preferable that the silica particles having a large particle diameter have a central particle diameter of 20 μm or more and that the silica particles having a small particle diameter have a central particle diameter of 0.5 μm or less. The content of the silica particles having a large particle diameter is preferably in the range of 1 or more and 20 or less times the content of the silica particles having a small particle diameter.

Further, the ratio of the central particle diameter of the silica particles having a small particle diameter to the central particle diameter of the silica particles having a large particle diameter is preferably 0.05 or more and 0.5 or less, and more preferably 0.1 or more and 0.4 or less.

When adjusting the elastic modulus, the ratio of calcium carbonate in the thermosetting resin composition is preferably 1 mass % or more and 20 mass % or less, and more preferably 5 mass % or more and 15 mass % or less so that the frame body 2 is not broken during loading.

Further, the thermal conductivity of the filler is preferably higher than that of the resin constituting the frame body 2. For example, when the thermal conductivity of the resin is less than 1.0 W/m·K, the frame body 2 can have a high thermal conductivity of 1.0 W/m·K or more with the filler added.

In addition to the above components, the thermosetting resin composition may include various additives such as a curing accelerator, a coupling agent, a mold release agent, a flame retardant, a colorant, and the like, which will be exemplified below. The thermosetting resin composition may also include various additives known in the art as necessary in addition to the additives exemplified below.

The curing accelerator is a catalyst for radically opening an epoxy group of the epoxy resin or radicalizing a reactive functional group of the curing agent to promote the polymerization reaction. The curing accelerator is not limited in particular, but is preferably an organophosphorus compound. Examples of the organophosphorus compound as the curing accelerator include triphenylphosphine, tri-o-tolylphosphine, tri-p-tolylphosphine, diphenylcyclohexylphosphine, tricyclohexylphosphine, tetra-n-butylphosphonium laurate, 1,2-bis(diphenylphosphino) acetylene, and the like. Among them, tri-p-tolylphosphine having excellent potential is preferable. When the total amount of the epoxy resin and the curing agent is 100 parts by mass, the organophosphorus compound is preferably in the range of 0.1 parts by mass or more and 5 parts by mass or less, and more preferably in the range of 0.5 parts by mass or more and 3 parts by mass or less. When the total amount of the epoxy resin and the curing agent is 100 parts by mass, if the amount of the organophosphorus compound is 0.5 parts by mass or more, the thermosetting resin composition can be cured quickly, and if the amount is 3 parts by mass or less, the thermosetting resin composition is stabilized without being cured during heating and melting before the molding, which tends to improve productivity.

The coupling agent can be used from the viewpoint of enhancing affinity and adhesion between the epoxy resin and the inorganic filler. Examples of the coupling agent includes silane coupling agents having a glycidyl group, a mercapto group, an amino group, an alkyl group, a urea group, or a vinyl group at the end. Among them, a silane coupling agent having a glycidyl group at the end is preferably used because the silane coupling agent has a high affinity for the epoxy resin and can express high adhesion with the inorganic filler.

When the amount of the silane coupling agent is too small, the surface modification effect on the inorganic filler may not be sufficiently exerted. On the other hand, when the amount of the silane coupling agent is too large, the excess silane coupling agent may degrade the performance such as the elastic modulus of the thermosetting resin composition. Therefore, the silane coupling agent is preferably in the range of 0.05 parts by mass or more and 5 parts by mass or less for 100 parts by mass of the inorganic filler, and more preferably in the range of 0.2 parts by mass or more and 2 parts by mass or less.

The mold release agent is used to ensure smooth mold release from the molding machine in the molding of the thermosetting resin composition. The mold release agent is not particularly limited, and a conventional mold release agent can be used. Specifically, examples of the mold release agent include carnauba wax, higher fatty acids such as montanic acid, stearic acid and the like, higher fatty acid metal salts such as metal soaps and the like, ester wax, polyolefin wax such as oxidized polyethylene, non-oxidized polyethylene, and the like. As the mold release agent, one kind may be used alone or two or more kinds may be used in combination.

When the total amount of the epoxy resin and the curing agent is 100 parts by mass, the release agent is preferably in the range of 0.1 parts by mass or more and 10 parts by mass or less, and more preferably in the range of 0.5 parts by mass or more and 5 parts by mass or less. When the total amount of the epoxy resin and the curing agent is 100 parts by mass, if the amount of the release agent is 0.5 parts by mass or more, the release property is likely to be sufficiently obtained, and if the amount is 10 parts by mass or less, the bonding property tends to be better.

The flame retardant is used to ensure the flame retardancy of the thermosetting resin composition. The flame retardant is not particularly limited, and a conventionally known flame retardant may be used. Examples of the flame retardant include organic or inorganic compounds including a bromine atom, an antimony atom, a nitrogen atom or a phosphorus atom, metal hydroxides, and the like. As the flame retardant, one kind may be used alone or two or more kinds may be used in combination.

The colorant is used to tone the resin composition. The colorant is not particularly limited, and a conventional colorant may be used. Examples of the colorant include known colorants such as carbon black, organic dyes, organic pigments, titanium oxide, red lead, Bengala, and the like. The content of the colorant can be appropriately selected according to the purpose, and the like. As the colorant, one kind may be used alone or two or more kinds may be used in combination. In the imaging module 100 according to the present embodiment, carbon black is preferable as carbon black has low gloss and prevents diffuse reflection of incident light. The content of carbon black is preferably in the range of, for example, 0.01 mass % or more and 1 mass % or less.

The frame body 2 used in the imaging module 100 according to the present embodiment is manufactured, for example, as follows.

The epoxy resin, the curing agent, the filler and the additives are mixed in prescribed amounts as prescribed materials constituting the above-described thermosetting resin composition, and the kneaded resin composition is obtained by heating and melting kneading. For the heating and melting kneading, a kneader, a roll, a biaxial kneader or the like which has been previously heated to a range of 70° C. or more and 120° C. or less can be used. Next, the kneaded resin composition is refined by using a mixer, a pulverizer or the like.

Next, the refined kneaded resin composition is again heated and melted in the range of 70° C. or more and 100° C. or less and poured into a mold previously heated in the range of 160° C. or more and 190° C. or less to make the composition thermally cured for a certain period of time. Thus, the frame body 2 is obtained as a molded body formed by the mold. Examples of the molding method include injection molding, compression molding, transfer molding, and the like. Among these methods, injection molding is preferable as it allows continuous production. When a sufficient curing time cannot be ensured at the molding stage, it is preferable that the main curing process is carried out after the molding.

The frame body 2 can be made to have a desired treatment and a shape by various methods. Specifically, for example, the mold for forming can be processed to a desired shape in advance to obtain the frame body 2 having a desired warpage and a desired shape. Examples of the method of forming a warpage in the frame body 2 include, in addition to the method of processing the mold, a method of grinding, and a method of bending by placing a fulcrum at each corner portion of the frame body 2 and applying a load to the middle portion of each side portion.

The surface of the frame body 2 can be roughened by various methods. Examples of the method of roughening the surface of the frame body 2 include wet blasting, sand blasting, laser treatment, and the like.

The first bonding member 5 is provided between the substrate 1 and the frame body 2 to bond the substrate 1 and the frame body 2. The second bonding member 6 is provided between the frame body 2 and the lid body 3 to bond the frame body 2 and the lid body 3.

The first bonding member 5 and the second bonding member 6 are not particularly limited, but each of them is a cured product of an adhesive, for example. As the adhesive for forming the first bonding member 5 and the second bonding member 6, a commercially available epoxy resin-based adhesive which forms a dense cured structure can be used from the viewpoint of moisture resistance and bonding strength. The adhesive may be appropriately blended with a curing agent, a filler, and the like. The curing method of the adhesive is not particularly limited, and a curing method such as drying curing, two-liquid mixing curing, energy curing (thermosetting or light curing), or the like can be selected as appropriate for the purpose.

For example, the adhesive forming the first bonding member 5 is preferably a thermosetting adhesive because the first bonding member 5 is interposed between the substrate 1 and the frame body 2. On the other hand, in the case of the adhesive forming the second bonding member 6, the adhesive is interposed between the frame body 2 and the lid body 3, and the adhesive seals the space surrounded by the side of the surface 1a of the substrate 1, which is the mounting surface of the imaging element 4, and the frame body 2. Therefore, when the thermosetting adhesive is used as the adhesive forming the second bonding member 6, the sealed space may expand while the adhesive is in an uncured state during heating. From the viewpoint of avoiding such expansion of the space, it is preferable that the adhesive forming the second bonding member 6 is a photocuring adhesive which does not require heating. Note that, after the curing of the photocuring adhesive has progressed sufficiently, the photocuring adhesive may be supplementally heated to perform thermosetting. Thus, the adhesives forming the first bonding member 5 and the second bonding member 6 are preferably energy curable resin composition cured by heat or light.

The thickness of the second bonding member 6 at the middle portion of the side of the frame body 2 is thicker than the thickness of the second bonding member 6 at the corner portion of the frame body 2. On the other hand, the thickness of the first bonding member 5 at the corner portion of the frame body 2 is thicker than the thickness of the first bonding member 5 at the middle portion of the frame body 2. Specific thickness ranges of the first bonding member 5 and the second bonding member 6 are as follows.

The thickness ranges of the first bonding member 5 and the second bonding member 6 are preferably 5 μm or more and 300 μm or less, respectively. When the thickness of the bonding member is 5 μm or more, a sufficient bonding effect can be obtained with respect to the substrate 1 and the frame body 2 which are adherends in the case of the first bonding member 5, and with respect to the frame body 2 and the lid body 3 which are adherends in the case of the second bonding member 6. When the thickness of the bonding member is 300 μm or less, distortion of the bonded body due to hardening shrinkage is minimized.

Further, the thicknesses of the first bonding member 5 and the second bonding member 6 are preferably thicker than the warpage amount of the frame body 2 having a convex warpage on the side of the substrate 1. Since the thickness of the bonding member is thicker than the warpage amount, higher bonding stability can be ensured. When there is no portion where the thickness of the bonding member is thicker than the warpage amount of the frame body 2, it may be difficult to hermetically seal the imaging element 4 on the substrate 1 with a high degree of parallelism to the imaging element 4.

Note that the thickness of the second bonding member 6 at the corner portion of the frame body 2 is preferably 15 μm or less. When the thickness of the second bonding member 6 at the corner portion of the frame body 2 is 15 μm or less, heat from the frame body 2 can be efficiently transferred to the lid body 3.

The lid body 3 is a plate-like member for sealing a space surrounded by the side of the surface 1a of the substrate 1, which is a mounting surface of the imaging element 4, and the frame body 2. When the lid body 3 is used for the imaging module 100 as in the present embodiment, the lid body 3 is a translucent member that is transparent to the light targeted by the imaging module 100 such as visible light. Examples of the material used as the lid body 3 include plastic, glass (borosilicate glass, quartz glass, alkali-free glass, heat-resistant glass, and the like), quartz, and the like. An anti-reflection coating or an infrared cut coating may be provided on the surface of the lid body 3. When a light-curable adhesive is used for the second bonding member 6, it is preferable that the lid body 3 has sufficient light transmittance to the wavelength of light for curing the light-curable adhesive. Since the thickness of the lid body 3 is required to be flat after installation, it is preferable that the thickness of the lid body 3 is in the range of 0.1 mm or more and 2 mm or less, and more preferably in the range of 0.5 mm or more and 1.5 mm or less.

When the linear expansion coefficient of the substrate 1 is set to “αb”, the linear expansion coefficient of the frame body 2 is set to “αf”, and the linear expansion coefficient of the lid body 3 is set to “αc”, from the viewpoint of sufficiently suppressing the distortion of the lid body 3, it is preferable that these linear expansion coefficients satisfy the following large and small relationship.

$$α c < α f < α b$$

By satisfying this large and small relationship, the warpage of the entire imaging module 100 due to thermal deformation during bonding can be suppressed.

The imaging element 4 is, for example, a semiconductor element such as a complementary metal oxide semiconductor (CMOS) image sensor, a charge coupled device (CCD) image sensor, or the like. As illustrated in FIG. 2A, the imaging element 4 is mounted on the surface 1a of the substrate 1 and is electrically connected to the electrode of the substrate 1 by the metal wirings 7. The imaging element 4 may be mounted on the substrate 1 by a flip-chip bonding manner.

In the imaging element 4, the surface facing the lid body 3 is a light incident surface. The light incident surface can be formed by the topmost surface layer of a multilayer film provided on a semiconductor substrate having a light receiving surface. The multilayer film includes a layer having an optical function such as a color filter layer, a microlens layer, an anti-reflection layer, a light-shielding layer, and the like, a layer having a mechanical function such as a planarization layer and the like, a layer having a chemical function such as a passivation layer and the like, and the like.

As described above, according to the present embodiment, since the thickness of the second bonding member 6 bonding the frame body 2 and the lid body 3 is thicker at the middle portion of the side portion of the frame body 2 than at the corner portion of the frame body 2, the distortion of the lid body 3 caused by the operational heat generation of the imaging element 4 can be suppressed.

In the imaging module 100 according to the present embodiment in which the distortion of the lid body 3 is suppressed, for example, the difference between the maximum value of a distance from the substrate 1 to the lid body 3 and the minimum value of the distance is 100 μm or less, and the distortion of the lid body 3 is sufficiently reduced. Therefore, the deterioration of image quality due to the deviation of the optical axis can be further suppressed.

Note that, in the above-described example, the shape of the frame body 2 is not limited to a shape where the side in contact with the first bonding member 5 is convex toward the substrate 1. For example, the surface of the frame body 2 on the side in contact with the first bonding member 5 may be parallel to the main surface of the substrate 1.

### EXAMPLE

Next, the present embodiment will now be described in more detail with reference to examples and comparative examples, but the present disclosure is not limited by the following examples.

First, a measurement method used as an evaluation method for the imaging modules of the examples and the comparative examples will be described. The imaging modules of the examples and the comparative examples were evaluated by measuring the flatness of the lid body 3 as follows.

In the measurement, first, the imaging module 100 of each of the examples and the comparative examples prepared as described below was operated as electronic equipment, and the imaging element 4 was raised to 90° C. At this time, the imaging module 100 was placed on a surface plate, the height of the lid body 3 was measured using a laser displacement meter, and the flatness of the lid body 3 was evaluated based on the measurement result. The flatness was the amount of deviation of the use surface from a geometrically correct plane, and was expressed as the dimension of the interval when the use surface was sandwiched between two geometrically correct parallel planes and the interval between the two parallel planes was the smallest. Therefore, the smaller the flatness was, the higher the flatness was. In this measurement, the use surface was the lid body 3, and the difference between the minimum value and the maximum value of the height of the lid body 3 from the surface plate measured using the laser displacement meter was the interval at which the interval between the two parallel planes was minimum. As the evaluation criteria, four evaluation criteria were used in relation to the deviation of the optical axis of the incident light as affected by the flatness of the lid body 3. That is, the evaluation criteria were used with “A (excellent)” when flatness was less than 5 μm, “B (good)” when flatness was 5 μm or more but less than 10 μm, “C (acceptable)” when flatness was 10 μm or more but less than 15 μm, and “D (impossible)” when flatness was 15 μm or more. The deviation of the optical axis of the incident light causes degradation of the image imaged by the imaging module 100.

### Example 1

In Example 1, the imaging module 100 illustrated in FIG. 1 to FIG. 2B was prepared. In the following explanation, the longer direction of the imaging module 100 in a plan view viewed in the direction perpendicular to the surface 1a is referred to as an X direction and the shorter direction as a Y direction. In the imaging module 100, a glass epoxy substrate which was a plate-like rigid printed wiring board was used as the substrate 1, and a CMOS image sensor was mounted as the imaging element 4 on the substrate 1. As the lid body 3, a translucent member made of crystal glass with a countermeasure against a-ray was prepared. The dimensions of the glass epoxy substrate 1 were 0.8 mm in thickness, 54 mm in outer diameter in the X direction, and 43 mm in outer diameter in the Y direction. The dimensions of the lid body 3 were 0.5 mm in thickness, 53 mm in the X-direction, and 42 mm in the Y-direction. The linear expansion coefficients of the substrate 1 and lid body 3 were 14 ppm/K and 6 ppm/K, respectively. The frame body 2 was prepared according to the following procedure.

A mixture was obtained by mixing 7.6 mass % of the epoxy resin (multifunctional epoxy resin made by Nippon Kayaku Co., Ltd., trade name EPPN-502H), 4.7 mass % of the curing agent (novolac type phenol resin made by DIC Corporation, trade name TD-2131), 69 mass % of the silica particles (made by Denka Company Limited, average particle size 24 μm, trade name FB-950), 6.9 mass % of the silica particles (made by Denka Company Limited, 0.4 μm average particle size, trade name SFP-20M), 10 mass % of calcium carbonate (made by Shiraishi Kogyo Kaisha, Ltd., trade name Brilliant-1500), 0.2 mass % of the organophosphorus compound: tri-p-tolylphosphine (made by Hokko Chemical Industry Co., Ltd., trade name TPTP), 0.7 mass % of the silane coupling agent (made by Shin-Etsu Chemical Co., Ltd., glycidyl terminated, trade name KBM-403), 0.7 mass % of magnesium stearate (made by Sakai Chemical Industry Co., Ltd., trade name SM-1000), and 0.2 mass % of carbon black (made by Mitsubishi Chemical Corporation, trade name MA-100) at ordinary temperature. Next, the resulting mixture was heated and kneaded by a continuous biaxial kneader (made by The Japan Steel Works, Ltd., trade name TEX-44α) at 120° C. to obtain the kneaded resin composition. After cooling the kneaded resin composition, the kneaded resin composition was ground and mixed in a mixer (made by Kawata MFG. Co., Ltd., trade name SMV-100) to obtain the thermosetting resin composition. The obtained thermosetting resin composition was molded using an injection molding machine for thermosetting resin (made by Shibaura Machine Co., Ltd., trade name RC75SXR) and a mold shaped as the frame body 2 at the cylinder temperature of 80° C., the mold temperature of 180° C., and the curing time of 50 seconds to obtain the molded body. After the molding, the molded body obtained was heated at 180° C. for 8 hours to obtain the frame body 2. At this time, the mold was processed so that each side portion of the frame body 2 was warped in an arc shape, and the frame body 2 having a warpage of 100 μm in each side portion was obtained. The dimensions of the frame body 2 was 1.54 mm in thickness, 54 mm in outer diameter in the X direction, and 43 mm in outer diameter in the Y direction. The linear expansion coefficient of the frame body 2 was 11 ppm/K.

A thermosetting adhesive (made by 3M Japan Limited, trade name EW2050) was used as the adhesive for forming the first bonding member 5. The thermosetting adhesive was applied to the substrate 1 by a dispenser so as to be sealable after bonding. Then, the frame body 2 was placed on the thermosetting adhesive so as to have a convex warpage protruding toward the substrate 1 side, and a load was applied to the frame body 2 so that the substrate 1 and the frame body 2 were parallel to each other. Then, the first bonding member 5 was obtained by curing the thermosetting adhesive by heating at 120° C. to 150° C. At this time, the thickness of the first bonding member 5 at the corner portion of the frame body 2 was 115 μm, and the thickness of the first bonding member 5 at the middle portion of the side portion of the frame body 2 was 15 μm.

An ultraviolet curable adhesive (made by Kyoritsu Chemical & Co., Ltd., trade name World Rock 5210) was used as the adhesive for forming the second bonding member 6. The ultraviolet curable adhesive was also a thermosetting adhesive. The ultraviolet curable adhesive is applied by a dispenser on the surface 2b which was the bonding surface on the frame body 2 so that the imaging element 4 is sealed tightly in a space surrounded by the substrate 1, the frame body 2 and the lid body 3 after the bonding. Further, the surface 3a which is the bonding surface of the lid body 3 was brought into contact with the ultraviolet curable adhesive so that the substrate 1 and the lid body 3 were parallel to each other, and the ultraviolet curable adhesive was cured and bonded by irradiating ultraviolet ray using an LED light source having a wavelength of 365 nm. After the bonding by the ultraviolet ray, the imaging module 100 of Example 1 was obtained by heating at 80° C. to 100° C.

In the imaging module 100 of Example 1 obtained as described above, the thickness of the second bonding member 6 at the corner portion of the frame body 2 was 15 μm, and the thickness of the second bonding member 6 at the middle portion of the side portion of the frame body 2 was 115 μm. Note that FIG. 3 illustrates the positions of the middle portions of the side portions of the frame body 2 with M1 to M4, and the positions of the corner portions with C1 to C4.

In the present example, the adhesive for forming the first bonding member 5 was applied on the substrate 1, and the adhesive for forming the second bonding member 6 was applied on the frame body 2, but in either case, there is no limit to which of the adherends the adhesive is applied to. In addition, after the members are bonded with the adhesive, the thickness of the bonding member to be formed may be adjusted by injecting the additional adhesive between the members.

### Example 2

In Example 2, the thickness of the first bonding member 5 at the corner portion of the frame body 2 was set to 65 μm, and the thickness of the first bonding member 5 at the middle portion of the side portion of the frame body 2 was set to 15 μm. The thickness of the second bonding member 6 at the corner portion of the frame body 2 was set to 15 μm, and the thickness of the second bonding member 6 at the middle portion of the side portion of the frame body 2 was set to 65 μm. By forming in the same manner as in Example 1 except for these points, the imaging module 100 of Example 2 was obtained.

### Example 3

In Example 3, the thickness of the first bonding member 5 at the corner portion of the frame body 2 was set to 25 μm, and the thickness of the first bonding member 5 at the middle portion of the side portion of the frame body 2 was set to 15 μm. The thickness of the second bonding member 6 at the corner portion of the frame body 2 is 15 μm, and the thickness of the second bonding member 6 at the middle portion of the side portion of the frame body 2 is 25 μm. By forming in the same manner as in Example 1 except for these points, the imaging module 100 of Example 3 was obtained.

### Example 4

In Example 4, the thickness of the first bonding member 5 at the corner portion of the frame body 2 was set to 120 μm, and the thickness of the first bonding member 5 at the middle portion of the side portion of the frame body 2 was set to 20 μm. The thickness of the second bonding member 6 at the corner portion of the frame body 2 was set to 20 μm, and the thickness of the second bonding member 6 at the middle portion of the side portion of the frame body 2 was set to 120 μm. By forming in the same manner as in Example 4 except for these points, the imaging module 100 of Example 2 was obtained.

### Example 5

In Example 5, using the frame body 2 having a warpage of 110 μm, the thickness of the first bonding member 5 at the corner portion of the frame body 2 was set to 125 μm, and the thickness of the first bonding member 5 at the middle portion of the side portion of the frame body 2 was set to 15 μm. The thickness of the second bonding member 6 at the corner portion of the frame body 2 is 15 μm, and the thickness of the second bonding member 6 at the middle portion of the side portion of the frame body 2 is 125 μm. By forming in the same manner as in Example 1 except for these points, the imaging module 100 of Example 5 was obtained.

### Example 6

FIG. 4 is a sectional view illustrating the imaging module 100 of Example 6, corresponding to the sectional view illustrated in FIG. 2B. In Example 6, as illustrated in FIG. 4, the frame body 2 having a shape, in which only the surface 2b of the frame body 2 on the side of the lid body 3 was gouged out 100 μm in a convex shape protruding toward the side of the substrate 1, and the surface 2a of the frame body 2 on the side of the substrate 1 was flat, was used. The thicknesses of the first bonding member 5 at the corner portion and the middle portion of the side portion of the frame body 2 were uniformly set to 50 μm. By forming in the same manner as in Example 1 except for these points, the imaging module 100 of Example 6 was obtained.

### Example 7

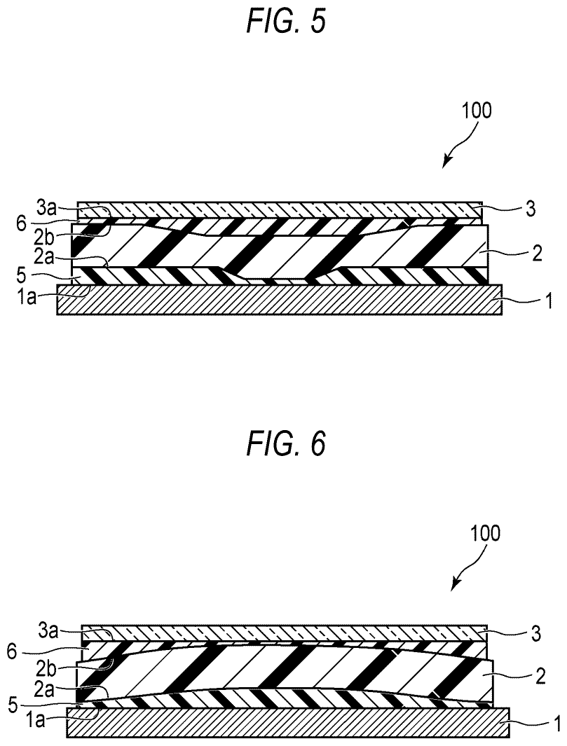

FIG. 5 is a sectional view illustrating the imaging module 100 of Example 7, corresponding to the sectional view illustrated in FIG. 2B. In Example 7, as illustrated in FIG. 5, the frame body 2 having a shape, in which only the corner portion in the surface 2b of the frame body 2 on the side of the lid body 3 protrudes toward the side of the lid body 3 and only the middle portion of the side portion in the surface 2a of the frame body 2 on the side of the substrate 1 protrudes toward the side of the substrate 1, was used. By forming in the same manner as in Example 1 except for these points, the imaging module 100 of Example 7 was obtained.

### Comparative Example 1

FIG. 6 is a sectional view illustrating the imaging module 100 of Comparative Example 1, corresponding to the sectional view illustrated in FIG. 2B. In Comparative Example 1, as illustrated in FIG. 6, the frame body 2 was placed on the substrate 1 so as to have a convex warpage protruding toward the lid body 3, and the thickness of the first bonding member 5 at the corner portion of the frame body 2 was 15 μm and the thickness of the first bonding member 5 at the middle portion of the side portion of the frame body 2 was 115 μm. The thickness of the second bonding member 6 at the corner portion of the frame body 2 was 115 μm and the thickness of the second bonding member 6 at the middle portion of the side portion of the frame body 2 is 15 μm. By forming in the same manner as in Example 1 except for these points, the imaging module 100 of Comparative Example 1 was obtained.

### Comparative Example 2

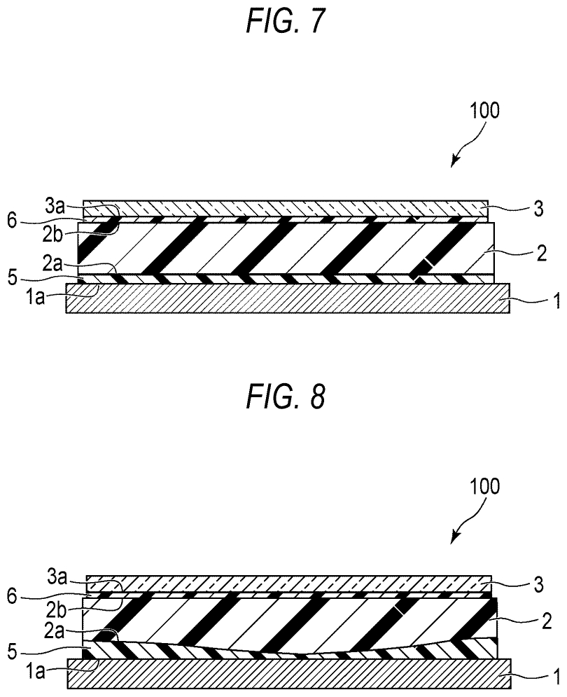

FIG. 7 is a sectional view illustrating the imaging module 100 of Comparative Example 2, corresponding to the sectional view illustrated in FIG. 2B. In Comparative Example 2, as illustrated in FIG. 7, the frame body 2 having a flat shape without any warpage on each side portion was used, and the thickness of the first bonding member 5 was uniformly 50 μm and the thickness of the second bonding member 6 was uniformly 15 μm. By forming in the same manner as in Example 1 except for these points, the imaging module 100 of Comparative Example 2 was obtained.

### Comparative Example 3

FIG. 8 is a sectional view illustrating the imaging module 100 of Comparative Example 3, corresponding to the sectional view illustrated in FIG. 2B. In Comparative Example 3, as illustrated in FIG. 8, the frame body 2 having a shape in which only the surface 2a of the frame body 2 on the side of the substrate 1 was protruded toward the side of the substrate 1 with a raised convex shape of 100 um, and the surface 2b of the frame body 2 on the side of the lid body 3 had a flat shape. The thickness of the first bonding member 5 at the corner portion of the frame body 2 was 115 μm, and the thickness of the first bonding member 5 at the middle portion of the side portion of the frame body 2 was 15 μm. The thicknesses of the second bonding member 6 at the corner portion and at the middle portion of the side portion of the frame body 2 were 15 μm. By forming in the same manner as in Example 1 except for these points, the imaging module 100 of Comparative Example 3 was obtained.

Details of the above-described examples and the comparative examples and evaluation results obtained for the examples and the comparative examples are illustrated in Table 1.

TABLE 1

| | | | First Bonding Member [μm] | | | Second Bonding Member [μm] | | | |
|---|---|---|---|---|---|---|---|---|---|
| | | | Bonding Member between | | | Bonding Member between | | | |
| | | | Frame Body and Substrate | | | Lid Body and Frame Body | | | |
| | | Flat- | Thick- | Thick- | | Thick- | Thick- | | |
| | Warpage | ness | ness | ness | | ness | ness | | |
| | of Frame | of | of | of | | of | of | | Evaluation |
| | Body [μm] | Frame | Middle | Corner | Thicknes | Middle | Corner | Thicknes | Flatness |
| | (Convex: + | Body | Portion | Portion | Difference | Portion | Portion | Difference | of Lid |
| | Concave: −) | [μm] | H1 | H2 | \|H1 − H2\| | h′1 | h′2 | \|h′1 − h′2\| | Body |
| Example 1 | −100 | 100 | 15 | 115 | 100 | 115 | 15 | 100 | 3 μm A |
| Example 2 | −50 | 50 | 15 | 65 | 50 | 65 | 15 | 50 | 4 μm A |
| Example 3 | −10 | 10 | 15 | 25 | 10 | 25 | 15 | 10 | 8 μm B |
| Example 4 | −100 | 100 | 20 | 120 | 100 | 120 | 20 | 100 | 12 μm C |
| Example 5 | −110 | 110 | 15 | 125 | 110 | 125 | 15 | 110 | 9 μm B |
| Example 6 | −100 | 100 | 50 | 50 | 0 | 115 | 15 | 100 | 14 μm C |
| | (upper | | | | | | | | |
| | surface | | | | | | | | |
| | only) | | | | | | | | |
| Example 7 | 0 | 50 | 15 | 65 | 50 | 65 | 15 | 50 | 12 μm C |
| | (special | | | | | | | | |
| | shape) | | | | | | | | |
| Comparative | 100 | 100 | 115 | 15 | 100 | 15 | 115 | 100 | 25 μm D |
| Example 1 | | | | | | | | | |
| Comparative | 0 | 0 | 50 | 50 | 0 | 15 | 15 | 0 | 21 μm D |
| Example 2 | | | | | | | | | |
| Comparative | 100 | 100 | 15 | 115 | 0 | 15 | 15 | 0 | 18 μm D |
| Example 3 | (lower | | | | | | | | |
| | surface | | | | | | | | |
| | only) | | | | | | | | |

As shown in Table 1, in each of the imaging modules 100 of Examples 1 to Example 7, the distortion of the lid body 3 caused by the operational heat generation of the imaging element 4 can have been suppressed.

Comparing Example 1, Example 2, and Example 3, Example 1 was the most effective in suppressing the distortion of the lid body 3, followed by Example 2. This was due to the following reasons. That is, in Example 1, as compared with Example 2 and Example 3, there is a large difference in the thickness of the second bonding member 6 between at the middle portion of the side portion and at the corner portion in the frame body 2. Therefore, in Example 1, heat generated by the imaging element 4 can have been transferred more efficiently to the corner portion of the lid body 3 having the lowest temperature in the temperature distribution of the lid body 3. As a result, in Example 1, the distortion caused by temperature unevenness of the lid body 3 can have been suppressed to a smaller extent by equalizing the heat of the lid body 3. In Example 1, temperature unevenness of the lid body 3 was suppressed to 2° C. or less.

Comparing Example 1 and Example 6, the distortion of the lid body 3 was suppressed in Example 1 more than in Example 6. This is because, in Example 1, since the frame body 2 itself was warped, there was a large difference in the thickness of the first bonding member 5 between at the middle portion of the side portion and at the corner portion in the frame body 2, and as a result, heat obtained from the middle portion of the side portion of the lower surface of the frame body 2 closest to the imaging element 4, which is the heat generation source, can have been efficiently transferred to the corner portion of the lid body 3. In the case of Example 6, heat was transmitted so that heat spread to the lower surface of the frame body 2, and the heat transfer path increased.

Comparing Example 1 and Example 7, the distortion of the lid body 3 can have been suppressed in Example 1 more than in Example 7. This is because Example 1 was more advantageous in equalizing the heat of the lid body 3 having temperature unevenness in a concentric shape facing the imaging element 4 since the warpage was formed smoothly in an arc shape.

In contrast, in Comparative Example 1, since the frame body 2 has a convex warpage protruding toward the lid body 3, the difference in the thickness of the bonding member between at the middle portion and at the corner portion of the side portion in the frame body 2 was opposite to the configuration of the examples. In the configuration of Comparative Example 1, since the second bonding member 6 was thick relative to the corner portion of the lid body 3, and the frame body 2, which is a heat transfer path, was formed so as to move away from the corner portion of the lid body 3, the heat cannot have been equalized and the distortion of the lid body 3 cannot have been suppressed.

In Comparative Example 2, since the frame body 2 had a flat shape, the second bonding member 6 has a uniform thickness. In the configuration of Comparative Example 2, since the heat transmitted to the lid body 3 through the frame body 2 was most abundant from the middle portion of the side portion in the frame body 2 or was almost uniform, temperature unevenness of the lid body 3 caused by heat generation by the imaging element 4 cannot have been reduced. Therefore, in the configuration of Comparative Example 2, the distortion of the lid body 3 cannot have been suppressed.

In Comparative Example 3, as in Comparative Example 2, since the second bonding member 6 had a uniform thickness, the distortion of the lid body 3 cannot have been suppressed.

Further, when each of the imaging modules 100 of Example 1 to Example 7 was stored in a housing and operated as a camera which is an imaging apparatus, a good image can have been obtained for a long time even if the temperature rose due to the operational heat generation.

### Second Embodiment

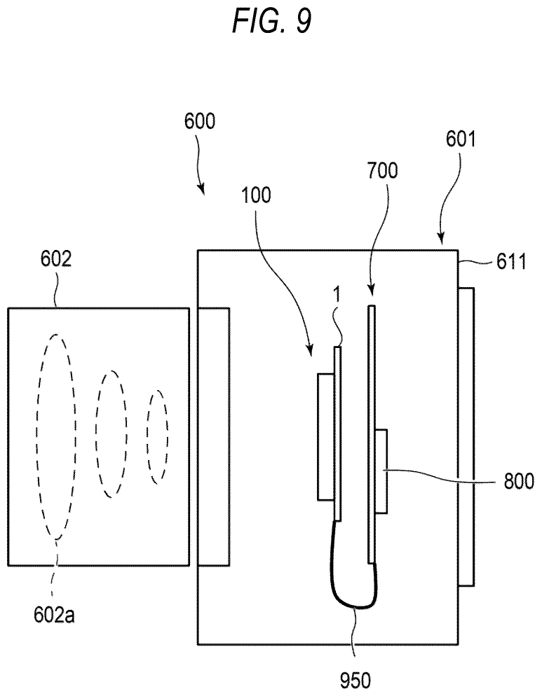

Electronic equipment according to a second embodiment of the present disclosure will be described with reference to FIG. 9. FIG. 9 is a schematic diagram illustrating a digital camera 600 as an example of the electronic equipment according to the second embodiment. In the present embodiment, a digital camera 600 as an imaging apparatus which is an example of the electronic equipment using the imaging module 100 according to the first embodiment will be described. Note that the imaging apparatus is a generic term for not only a digital camera but also electronic equipment including the imaging module such as a smartphone or a tablet.

The digital camera 600 according to the present embodiment is a digital camera with an interchangeable lens and includes a camera body 601. A lens unit 602 including one or a plurality of lenses 602a is detachably attached to the camera body 601. The camera body 601 includes a housing 611, the imaging module 100 according to the first embodiment, and a printed circuit board 700. The imaging module 100 and the printed circuit board 700 are arranged inside the housing 611.

The imaging module 100 and the printed circuit board 700 are electrically connected by a cable 950. As described in the first embodiment, the imaging module 100 is equipped with an imaging element 4 that is a semiconductor element (see FIG. 2A). The imaging element 4 is, for example, a CMOS image sensor or a CCD image sensor. The imaging element 4 has a function of converting light incident through the lens unit 602 into an electric signal.

An image processing device 800 is mounted on the printed circuit board 700. The image processing device 800 is, for example, a digital signal processor. The image processing device 800 has a function of acquiring an electric signal from the imaging element 4, performing processing for correcting the acquired electric signal, and generating image data.

According to the present embodiment, since the distortion of the lid body 3 caused by the operational heat generation of the imaging element 4 can be suppressed in the imaging module 100, the quality of the image captured by the digital camera 600 can be improved.

The embodiments described above can be modified as necessary within the scope that does not depart from the technical idea. For example, a plurality of the embodiments can be combined. Further, some of the matters in at least one embodiment can be deleted or replaced. Further, new matters can be added to at least one embodiment.

Note that the contents of the disclosure in the present specification include not only what is explicitly described herein, but also all matters that can be understood from the present specification and the drawings attached to the present specification.

According to the present disclosure, the distortion of the lid body caused by the operational heat generation of the imaging element can be suppressed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-066313, filed Apr. 16, 2024, which is hereby incorporated by reference herein in its entirety.

What is claimed is:

1. An imaging module comprising:
a substrate;
an imaging element mounted on the substrate;
a frame body including a plurality of side portions and a corner portion and provided outside the imaging element in a plan view;
a first bonding member provided between the substrate and the frame body;
a lid body that is translucent and covers a space formed by the substrate and the frame body; and
a second bonding member provided between the frame body and the lid body,
wherein a thickness of the second bonding member at a middle portion of the side portion is thicker than a thickness of the second bonding member at the corner portion.

2. The imaging module according to claim 1, wherein a thickness of the first bonding member at the corner portion is thicker than a thickness of the first bonding member at the middle portion.

3. The imaging module according to claim 1, wherein a distance from the middle portion to the lid body is longer than a distance from the corner portion to the lid body.

4. The imaging module according to claim 1, wherein a distance from the corner portion to the substrate is longer than a distance from the middle portion to the substrate.

5. The imaging module according to claim 1, wherein the side portion of the frame body has a convex warpage protruding toward a side of the substrate.

6. The imaging module according to claim 1, wherein the thickness of the second bonding member at the corner portion is 15 um or less.

7. The imaging module according to claim 1, wherein a flatness of the frame body is 100 μm or less.

8. The imaging module according to claim 1, wherein the frame body has a warpage, and
wherein an amount of the warpage of the frame body is 10 μm or more.

9. The imaging module according to claim 1, wherein the frame body has a warpage, and
wherein thicknesses of the first bonding member and the second bonding member are thicker than an amount of the warpage of the frame body.

10. The imaging module according to claim 1, wherein a thermal conductivity of the frame body is greater than thermal conductivities of the first bonding member and the second bonding member.

11. The imaging module according to claim 1, wherein a difference between the maximum value of a distance from the substrate to the lid body and the minimum value of the distance is 100 μm or less.

12. The imaging module according to claim 1, wherein, when a linear expansion coefficient of the substrate is “αb”, a linear expansion coefficient of the frame body is “αf”, and a linear expansion coefficient of the lid body is “αc”, αc<αf<αb is satisfied.

13. The imaging module according to claim 1, wherein the frame body is a cured thermosetting resin.

14. The imaging module according to claim 1, wherein the frame body is a molded body formed by injection molding.

15. An imaging apparatus comprising:
a housing; and
the imaging module according to claim 1 arranged inside the housing.
